(19) United States
(12) Patent Application Publication
(10) Pub. No.: US 2006/0207971 A1
(43) Pub. Date: Sep. 21, 2006

(54) Atmospheric transfer chamber, processed object transfer method, program for performing the transfer method, and storage medium storing the program

(75) Inventors: Tsuyoshi Moriya, Nirasaki-shi (JP); Takaaki Hirooka, Nirasaki-shi (JP); Akitaka Shimizu, Nirasaki-shi (JP); Satoshi Tanaka, Nirasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/376,163

(22) Filed: Mar. 16, 2006

Related U.S. Application Data
(60) Provisional application No. 60/666,703, filed on Mar. 31, 2005.

(30) Foreign Application Priority Data
Mar. 17, 2005 (JP) 2005-078092

(51) Int. Cl. C23F 1/00; H01L 21/306; B44C 1/22

(52) U.S. Cl. 216/67; 156/345.1

(57) ABSTRACT

An atmospheric transfer chamber, connected to an object processing chamber for processing a target object by using a plasma of a halogen-based gas, for transferring the target object therein, the atmospheric transfer chamber includes a dehumidifying unit for dehumidifying air in the atmospheric transfer chamber. The dehumidifying unit includes a desiccant filter, a cooling unit for cooling the air introduced into the atmospheric transfer chamber, and an air conditioner. The atmospheric transfer chamber is connected to a reaction product removal chamber for removing reaction products of a halogen-based gas attached to the target object, wherein halogen in reaction products attached to the target object is reduced.

### CROSS-REFERENCE TO RELATED APPLICATIONS

This document claims priority to Japanese Patent Application Number 2005-78092, filed Mar. 17, 2005 and U.S. Provisional Application No. 60/666,703, filed Mar. 31, 2005, the entire content of which are hereby incorporated by reference.

1. Field of the Invention

The present invention relates to an atmospheric transfer chamber, a processed object transfer method, a program for performing the transfer method, and a storage medium storing the program; and, more particularly, to an atmospheric transfer chamber for transferring an object that is processed by a plasma of a halogen-based gas.

2. Background of the Invention

Typically, in a substrate (hereinafter, referred to as a “wafer”) that is a target object formed of silicon (Si) for a semiconductor device, a trench (groove) is formed therein by etching a polysilicon layer on the wafer in order to form a gate electrode and the like. The etching of the polysilicon layer is performed in a processing chamber by using a halogen-based processing gas, for example, hydrogen bromide gas (HBr) and chlirine gas (Cl₂).

In the etching of the polysilicon layer, silicon in the wafer reacts with some of the processing gas remaining without being converted into a plasma, thereby generating corrosive reaction products, for example, silicon bromide (SiBr₄) or silicon chloride (SiCl₄). The generated corrosive reaction products are attached to a sidewall of a trench 102 between gate electrodes 101 of the wafer 100, as shown in FIG. 10, thereby forming a deposited film (passivation) 103. The deposited film 103 may cause a resistance or a short circuit in wiring in a semiconductor device fabricated from the wafer 100 and, thus, needs to be removed.

A conventional substrate processing apparatus for removing a deposited layer includes an etching chamber (processing chamber) and a corrosion passivation chamber. In the substrate processing apparatus, the wafer is exposed to a high-temperature steam in the corrosion passivation chamber to thereby make the corrosive reaction products of the deposited layer react with the steam. At this time, halogen in the corrosive reaction products is reduced by water, whereby the corrosive reaction products are resolved to be removed (see, e.g., U.S. Pat. No. 6,852,636).

However, in this substrate processing apparatus, in order that the wafer etched in the etching chamber is vacuum transferred to the corrosion passivation chamber, the corrosion passivation chamber needs to be arranged in a vacuum state, which inevitably complicates the configuration of the substrate processing apparatus.

Thus, recently, there is developed a substrate processing apparatus having the following configuration. First, a loader module, i.e., an atmospheric transfer chamber, is connected to a processing chamber. The loader module is coupled to a purge storage chamber for removing corrosive reaction products. In the purge storage chamber of the substrate processing apparatus, a loaded wafer is exposed to the atmosphere wherein the corrosive reaction products react with water in the atmosphere. Accordingly, halogen in the corrosive reaction products is reduced by water and the corrosive reaction products are resolved to produce halogen-based acid gas, e.g., hydrogen chloride (HCl) to be discharged (purged). Thus, the substrate processing apparatus can have a simple configuration.

However, in the substrate processing apparatus including the purge storage chamber, before the wafer etched in the processing chamber is loaded in the purge storage chamber, the wafer is transferred in the loader module wherein the corrosive reaction products on the wafer react with water in the atmosphere to produce halogen-based acid gas such as HCl or HBr as shown in the following equations.
SiBr₄+H₂O→SiO₂+4HBr↑
SiCl₄+H₂O→SiO₂+4HCl↑

The produced halogen-based acid gases corrode an inner wall of the loader module and a surface of a wafer transfer arm, which are formed of metal such as stainless steel or aluminum, thereby covering them with an oxide (e.g., Fe₂O₃ or Al₂O₃) layer. The oxide layer is peeled from the inner wall and the surface due to the vibration generated while the wafer is transferred by the wafer transfer arm and turns into particles to be attached to the surface of the wafer, which in turn deteriorates quality of the semiconductor device fabricated from the wafer. Further, in order to remove the oxide layer from the inner wall and the surface, an inside of the loader module should be cleaned regularly and an operation rate of the substrate processing apparatus is reduced.

### SUMMARY OF THE INVENTION

It is, therefore, an object of the present invention to provide an atmospheric transfer chamber, a processed object transfer method, a program for performing the transfer method, and a storage medium storing the program capable of preventing quality of a semiconductor device fabricated from a target object from deteriorating while improving an operation rate of an object processing apparatus.

To achieve the object, in accordance with a first aspect of the present invention, there is provided an atmospheric transfer chamber, connected to an object processing chamber for processing a target object by using a plasma of a halogen-based gas, for transferring the target object therein, the atmospheric transfer chamber including a dehumidifying unit for dehumidifying air in the atmospheric transfer chamber. Since the inside of the atmospheric transfer chamber for transferring the target object processed by using a plasma of a halogen-based gas is dehumidified, reaction products of a halogen-based gas attached to the target object do not react with water, a halogen-based acid gas is prevented from being produced from the target object. As a result, generation of oxide is suppressed in the atmospheric transfer chamber, and it is possible to prevent the quality of a semiconductor device fabricated from the target object from being deteriorated and improve an operation rate of the object processing apparatus.

In the atmospheric transfer chamber, the dehumidifying unit may include a desiccant filter. Accordingly, the inside of the atmospheric transfer chamber can be efficiently dehumidified. Further, the desiccant filter can be recovered during a dehumidifying process, which, in turn, further improves an operation rate of the object processing apparatus.

In the atmospheric transfer chamber, the dehumidifying unit may include a cooling unit for cooling the air introduced into the atmospheric transfer chamber. Accordingly, the air inside the atmospheric transfer chamber can be efficiently dehumidified. Further, since the cooling unit can be easily arranged to be installed and the configuration of the atmospheric transfer chamber can be simplified.

In the atmospheric transfer chamber, the cooling unit may have a Peltier element, whereby the cooling unit can become compact.

In the atmospheric transfer chamber, the dehumidifying unit may include an air conditioner. Accordingly, the air inside the atmospheric transfer chamber can be efficiently dehumidified. Further, since the air conditioner can be easily arranged to be installed and the configuration of the atmospheric transfer chamber can be simplified.

The atmospheric transfer chamber may be connected to a reaction product removal chamber for removing reaction products of a halogen-based gas attached to the target object, wherein halogen in reaction products attached to the target object is reduced in the reaction product removal chamber. As a result, it is possible to prevent a semiconductor device fabricated from the target object from developing any abnormal defect.

In the atmospheric transfer chamber, the reaction product removal chamber may include a high-temperature steam supply unit for supplying high-temperature steam into the chamber, whereby it can promote reduction of halogen in the reaction products and resolution of the reaction products.

In the atmospheric transfer chamber, preferably, the high-temperature steam supply unit sprays the high-temperature steam toward the target object loaded into the reaction product removal chamber, or the target object loaded into the reaction product removal chamber is exposed to the supplied high-temperature steam, thereby definitely bringing the high-temperature steam into contact with the reaction products. Accordingly, it can promote reduction of halogen in the reaction products.

In the atmospheric transfer chamber, the reaction product removal chamber may include a supercritical substance supply unit for supplying a supercritical substance into the chamber, and the supercritical substance contains a halogen reducing agent for reducing halogen in reaction products. The supercritical substance has characteristics of the two phases. Due to its gaseous characteristic, the halogen reducing agent can enter into the trench of the target object, it can promote reduction of halogen in the reaction products attached to the sidewall of the trench and, thus, the reaction products can be resolved. Further, due to its liquid characteristic, it attracts the reaction products, whereby the reaction products can be surely removed from the trench.

In the atmospheric transfer chamber, preferably, the supercritical substance is formed of carbon dioxide, rare gas or water. Thus, the supercritical state can be easily realized, thereby facilitating the removal of the reaction products.

In the atmospheric transfer chamber, preferably, the reducing agent is formed of water or oxygenated water. Thus, it is possible to further promote the reduction of halogen in the reaction products.

Further, the atmospheric transfer chamber may include a container port for connecting the atmospheric transfer chamber with a container storing the target object; and a dehumidified air supply unit for supplying dehumidified air toward the container port. Accordingly, it is possible to prevent water from entering into the atmospheric transfer chamber from the container. Thus, reaction products of a halogen-based gas attached to the target object can be surely prevented from reacting with water.

Furthermore, the atmospheric transfer chamber may include an ion supply unit for supplying ions into the atmospheric transfer chamber, wherein the supplied ions make the charges to be removed from the target object that is likely to be charged by dehumidifying the inside of the atmospheric transfer chamber. Accordingly, it is possible to prevent the quality of a semiconductor device fabricated from the target object from deteriorating.

Moreover, the atmospheric transfer chamber may include an air heating unit for heating air supplied into the atmospheric transfer chamber, which makes halogen-based acid produced in the reaction between the reaction products attached to the target object and water be evaporated all the time. Accordingly, it is possible to prevent acid from being attached to the inner wall of the atmospheric transfer chamber and the surface of the unit disposed in the atmospheric transfer chamber. Therefore, generation of oxide can be further surely prevented in the atmospheric transfer chamber.

Still further, the atmospheric transfer chamber may include a container mounting table for mounting thereon a container storing the target object, wherein the container mounting table includes a container heating unit for heating the container. Accordingly, it is possible to remove water from the container and prevent water from entering into the atmospheric transfer chamber from the container, and reaction products can be surely prevented from reacting with water in the container.

Additionally, in accordance with the present invention, there is provided an atmospheric transfer chamber, connected to an object processing chamber for processing a target object by using a plasma of a halogen-based gas, for transferring the target object therein, the atmospheric transfer chamber including an interior heating unit for heating an inside of the atmospheric transfer chamber. Since the inside of the atmospheric transfer chamber for transferring the target object processed by using a plasma of a halogen-based gas is heated, halogen-based acid produced by reaction of reaction products of the halogen-based gas attached to the target object with water is evaporated all the time, thereby preventing the halogen-based acid from being attached to the inner wall of the atmospheric transfer chamber and the surface of the unit disposed in the atmospheric transfer chamber. As a result, generation of oxide is suppressed in the atmospheric transfer chamber and it is possible to prevent the quality of a semiconductor device fabricated from the target object from being deteriorated and improve an operation rate of the object processing apparatus.

In accordance with a second aspect of the present invention, there is provided a transfer method of a target object which is processed by using a plasma of a halogen-based gas, the method including the step of transferring the target object inside a dehumidified atmospheric transfer chamber.

In accordance with a third aspect of the present invention, there is provided a program executable on a computer for performing a transfer method of a target object which is processed by using a plasma of a halogen-based gas, including a transfer module for transferring the target object inside a dehumidified atmospheric transfer chamber.

In accordance with a fourth aspect of the present invention, there is provided a computer readable storage medium for storing therein a program executable on a computer for performing a transfer method of a target object which is processed by using a plasma of a halogen-based gas, wherein the program includes a transfer module for transferring the target object inside a dehumidified atmospheric transfer chamber.

In accordance with the transfer method of the target object processed, the program and the storage medium, since the target object processed by using a plasma of a halogen-based gas is transferred in a dehumidified atmospheric transfer chamber, reaction products of a halogen-based gas attached to the target object do not react with water, and a halogen-based acid gas is prevented from being produced from the target object. As a result, generation of oxide is suppressed in the atmospheric transfer chamber, and it is possible to prevent the quality of a semiconductor device fabricated from the target object from being deteriorated and improve an operation rate of the object processing apparatus.

In the storage medium, the program may include a load module for loading the target object into a reaction product removal chamber for removing reaction products of a halogen-based gas attached to the target object; and a reduction module for reducing halogen in reaction products attached to the loaded target object. Since the target object is loaded into the reaction product removal chamber for removing the reaction products of a halogen-based gas attached to the target object and, then, halogen in reaction products attached to the loaded target object is reduced, the reaction products can be resolved to be removed. As a result, it is possible to prevent a semiconductor device fabricated from the target object from developing any abnormal defect.

In the storage medium, the program may include a high-temperature steam supply module for supplying high-temperature steam into a reaction product removal chamber. Since high-temperature steam is supplied into the reaction product removal chamber, it can promote reduction of halogen in the reaction products and resolution of the reaction products.

In the storage medium, the program may include a supercritical substance supply module for supplying a supercritical substance into the reaction product removal chamber, and the supercritical substance contains a halogen reducing agent for reducing halogen in reaction products. The supercritical substance has characteristics of the two phases. Due to its gaseous characteristic, the halogen reducing agent can enter into the trench of the target object, it can promote reduction of halogen in the reaction products attached to the sidewall of the trench and, thus, the reaction products can be resolved. Further, due to its liquid characteristic, it attracts the reaction products, whereby the reaction products can be surely removed from the trench.

In the storage medium, the program may include a determination module for determining whether the target object is to be transferred inside the atmospheric transfer chamber or not depending on a humidity of the atmospheric transfer chamber. Since it is determined whether the target object is to be transferred inside the atmospheric transfer chamber or not depending on a humidity of the atmospheric transfer chamber, reaction products of a halogen-based gas attached to the target object can be surely prevented from reacting with water in the atmospheric transfer chamber.

### BRIEF DESCRIPTION OF THE DRAWINGS

The above and other objects and features of the present invention will become apparent from the following description of preferred embodiments, given in conjunction with the accompanying drawings, in which:

FIG. 1 is a plan view schematically showing a configuration of a substrate processing apparatus including an atmospheric transfer chamber in accordance with a first preferred embodiment of the present invention;

FIG. 2 represents a vertical sectional view showing the atmospheric transfer chamber cut along a line II-II shown in FIG. 1;

FIG. 3 depicts a vertical sectional view schematically showing a configuration of a dehumidifying unit shown in FIG. 2;

FIG. 4 represents a vertical sectional view showing an after treatment chamber cut along a line IV-IV shown in FIG. 1;

FIG. 5 is a flowchart showing a post-etching processing;

FIG. 6 depicts a cross sectional view showing a schematic configuration of an after treatment chamber connected to a loader module serving as an atmospheric transfer chamber in accordance with a second preferred embodiment;

FIG. 7 depicts a cross sectional view showing a schematic configuration of a loader module serving as an atmospheric transfer chamber in accordance with a third preferred embodiment;

FIG. 8 depicts a cross sectional view showing a schematic configuration of a loader module serving as an atmospheric transfer chamber in accordance with a fourth preferred embodiment;

FIG. 9 depicts a cross sectional view showing a schematic configuration of a loader module serving as an atmospheric transfer chamber in accordance with a fifth preferred embodiment; and

FIG. 10 shows a deposited film formed on a side surface of a trench.

### DETAILED DESCRIPTION OF THE PREFERRED EMBODIMENTS

Hereinafter, preferred embodiments of the present invention will be described with reference to the accompanying drawings. Like numerals will be assigned to like parts.

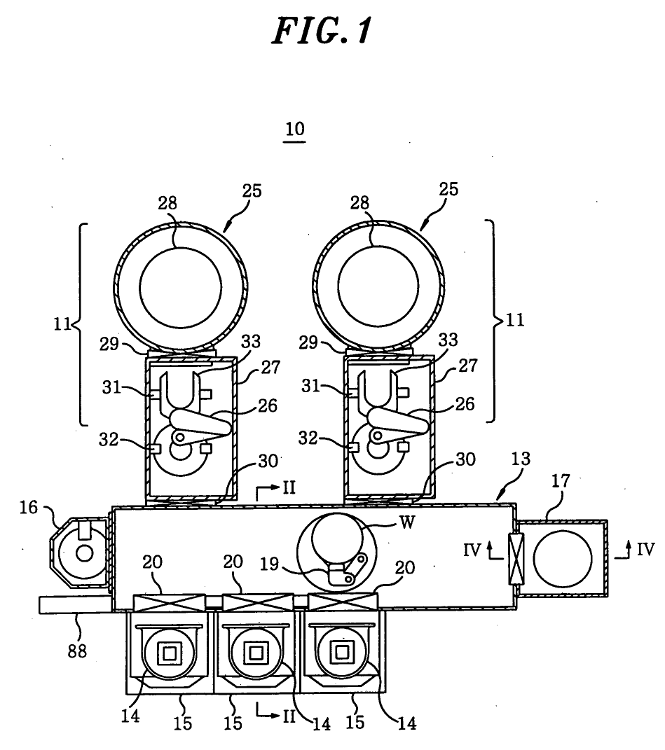

FIG. 1 is a plan view schematically showing a configuration of a substrate processing apparatus including an atmospheric transfer chamber in accordance with a first preferred embodiment of the present invention.

A substrate processing apparatus (object processing apparatus) 10 shown in FIG. 1 includes two process ships 11 for performing a reactive ion etching (RIE) process on a semiconductor wafer (hereinafter, referred to as a “wafer”) (target object) W and a loader module (atmospheric transfer chamber) 13 that is a rectangular common transfer chamber to which the two process ships 11 are connected.

In addition to the process ships 11, connected to the loader module 13 are three FOUP mounting tables (container mounting tables) 15, each one mounting thereon FOUP (Front opening Unified Pod) 14 serving as a container for storing twenty-five wafers W; an orienter 16 for performing a pre-alignment of the wafer W unloaded from the FOUP 14; and an after treatment chamber 17 for performing an after treatment on the RIE processed wafer W.

The two process ships 11 are connected to one of long sidewalls of the loader module 13. The three mounting tables 15 are connected to one of the other long sidewalls of the loader module 13 to face the process ships 11. The orienter 16 is coupled to one short sidewall of the loader module 13 and the after treatment chamber 17 is coupled to the other short sidewall thereof.

The loader module 13 includes a scalar dual-arm type transfer arm unit 19 for transferring the wafer W and three wafer loading ports (container ports) 20 formed at portions of the sidewall corresponding to the FOUP mounting tables 15. The wafer W is unloaded by the transfer arm unit 19 from the FOUP 14 mounted on the FOUP mounting table 15 through the loading port 20 to be loaded into the process ship 11, the orienter 16 or the after treatment chamber 17.

The process ship 11 includes a process module (object processing chamber) 25 which is a vacuum processing chamber for performing an RIE process on the wafer W and a load-lock module 27 having a link-shaped single pick type transfer arm 26 for transferring the wafer W to the process module 25.

The process module 25 includes a cylindrical processing chamber, wherein an upper and a lower electrode are spaced properly to perform the RIE process on the wafer W. Further, the lower electrode has therein an ESC 28 for chucking the wafer W by Coulomb force.

In the process module 25, a processing gas such as hydrogen bromide gas or chloride gas is introduced into the chamber and an electric field is generated between the upper and the lower electrode, whereby the processing gas is converted into a plasma to produce ions and radicals. Due to the action of the ions and radicals, the RIE process is performed on the wafer W and the polysilicon layer on the wafer W is etched.

The loader module 13 is maintained at an atmospheric pressure therein, whereas the process module 25 is kept at a vacuum level therein. Accordingly, the load-lock module 27 is configured as a vacuum preliminary transfer chamber whose inner pressure can be controlled by gate valves 29 and 30 disposed to communicate with the process module 25 and the loader module 13, respectively.

A transfer arm 26 is installed in an approximately central portion of the load-lock module 27. A first buffer 31 is installed between the transfer arm 26 and a process module 25 and a second buffer 32 is installed between the transfer arm 26 and the loader module 13. The first and the second buffer 31 and 32 are installed on a moving path of a wafer supporting portion (pick) 33 disposed at a leading end of the transfer arm 26. The RIE processed wafer W is temporarily moved upward from the path of the supporting portion 33 to thereby facilitate a smooth exchange of a processed wafer W with an unprocessed wafer W and vice versa.

Further, the substrate processing apparatus 10 includes a system controller (not shown) for controlling the operations of the process ship 11, the loader module 13, the orienter 16 and the after treatment chamber 17 (hereinafter, referred to as “every component”) and an operation controller 88 disposed at one end portion of the loader module 13.

The system controller controls an operation of every component based on a recipe (i.e., program) corresponding to an RIE process or a wafer transfer process. The operation controller 88 includes a display unit formed of, e.g., LCD (Liquid Crystal Display), wherein the display unit presents an operation status of every component.

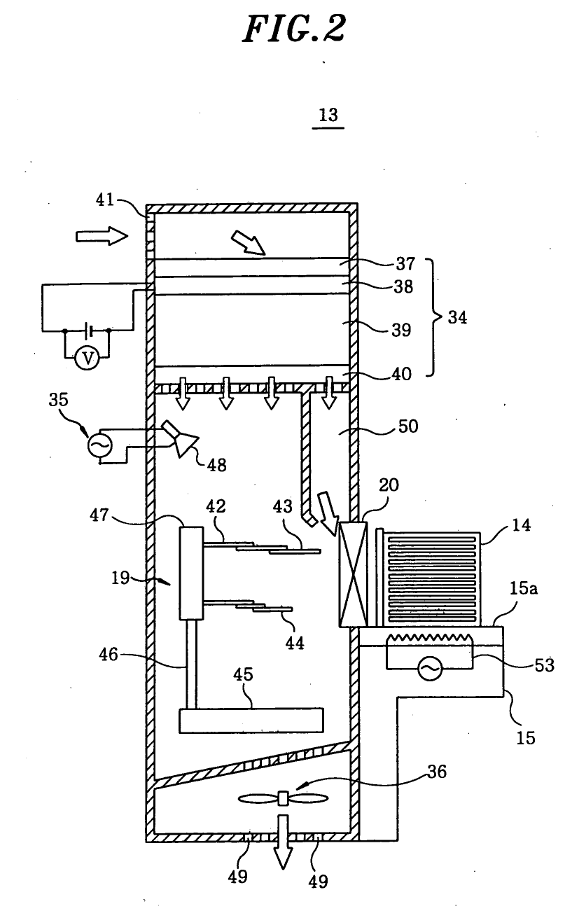

FIG. 2 represents a vertical sectional view showing the loader module 13 cut along a line II-II shown in FIG. 1. Further, upper and lower parts in FIG. 2 are referred to as an “upper side” and a “lower side”, respectively.

As shown in FIG. 2, the loader module 13 includes therein an FFU (Fan Filter Unit) 34 disposed at an upper side; the transfer arm unit 19 disposed at an almost same height as that of the FOUP 14 mounted on the FOUP mounting table 15; an ionizer (ion supply unit) 35 for supplying positive and negative ions; and a duct fan 36 disposed at a lower side. Further, air inlet openings 41 are provided on a sidewall of the loader module 13 at a place higher than FFU 34.

The FFU 34 includes a fan unit 37; a heating unit (air heating unit) 38; a dehumidifying unit (dehumidifier) 39; and a dust removal unit 40 installed in the order thus named from the top down.

The fan unit 37 has a fan (not shown) for blowing air downward; the heating unit 38 has a Peltier element (not shown) for heating the air blown by the fan unit 37; the dehumidifying unit 39 has a desiccant filter 55, to be described later, for dehumidifying the air that has passed through the heating unit 38; and the dust removal unit 40 has a filter (not shown) for collecting dust in the air that has passed through the dehumidifying unit 39.

The Peltier element embedded in the heating unit 38 is a semiconductor device that can be freely controlled to function as a cooler or a heater by using a DC current such that it can be used for a temperature control. If a DC current flows in the Peltier element, a temperature difference is developed between two sides of the Peltier element. Accordingly, heat is absorbed at a lower temperature side thereof while heat is emitted from a higher temperature side thereof. That is, the Peltier element can cool or heat a material in contact therewith. Further, since the Peltier element does not require a compressor or a coolant (e.g., flon) unlike a conventional heating unit or cooling unit, miniaturization and weight reduction can be realized and there is no ill effect on the environment.

By the FFU 34 having the above-mentioned configuration, the air introduced to the upper side in the loader module 13 is heated and dehumidified; and, then, dust in the air is removed to be supplied to the lower side in the loader module 13. Accordingly, the air in the loader module 13 is dehumidified.

The transfer arm unit 19 has a multi-joint transfer arm 42 configured to be expandable and contractible and a pick 43, attached to a leading end of the transfer arm 42, for mounting the wafer W thereon. Additionally, the transfer arm unit 19 has a multi-joint mapping arm 44 configured to be expandable and contractible and a mapping sensor (not shown), disposed to a leading end of the mapping arm 44, for emitting, e.g., a laser beam to detect presence of the wafer W. Base ends of the transfer arm 42 and the mapping arm 44 are respectively connected to an elevator 47 capable of moving up and down along an arm base supporting column 46 standing up from a base portion 45 of the transfer arm unit 19. Further, the arm base supporting column 46 is configured to be rotatable.

There is performed a mapping operation for detecting the number and position of the wafers W stored in the FOUP 14 by moving up and down an expanded mapping arm 44.

Since the transfer arm unit 19 can be expanded or contracted by the transfer arm 42 and can be rotated by the arm base supporting column 46, the wafer W mounted on the pick 43 can be freely transferred between the FOUP 14, the process ship 11, the orienter 16 and the after treatment chamber 17.

The ionizer 35 includes an approximately cylindrical outer electrode 48 and an inner electrode (not shown) disposed in an inner central portion of the outer electrode 48. While an AC voltage is applied between the outer electrode 48 and the inner electrode, for example, an N₂ gas is supplied from a gas supply source (not shown) to the outer electrode 48 to flow therein, whereby ions are generated to be supplied into the loader module 13.

Typically, the wafer W in a dehumidified atmosphere is likely to be charged to cause an abnormal discharge, thereby inflicting a damage on the wafer W. However, by spraying the ions generated from the ionizer 35 onto the surface of the wafer W mounted on the pick 43, the charges are removed from the wafer W, thereby preventing the wafer W from being damaged.

The duct fan 36 is disposed to face air discharge openings 49 of a plurality of through holes formed on a bottom surface of the loader module 13. The air inside the loader module 13 is discharged out of the loader module 13 via the air discharge openings 49.

The FOUP mounting table 15 has therein a heat transfer heater (container heating unit) 53 to heat the FOUP 14 which is mounted on the mounting surface 15a, wherein the heat transfer heater 53 is provided right underneath of the mounting surface 15a of the FOUP mounting table 15.

Further, disposed under the FFU 34 is a duct-shaped CDA (Clean Dry Air) curtain (dehumidified air supply unit) 50 for supplying the air supplied from the FFU 34 toward the loading port 20 installed on a side surface of the loader module 13. The air ejected from the CDA curtain 50 is a heated, dehumidified, and dust-free air same as that supplied from the FFU 34. Since the CDA curtain 50 supplies the heated and dehumidified air into the FOUP 14 through the loading port 20, the inside of the FOUP 14 is maintained in a dry state, which in turn prevents water from entering into the loader module 13 from the FOUP 14.

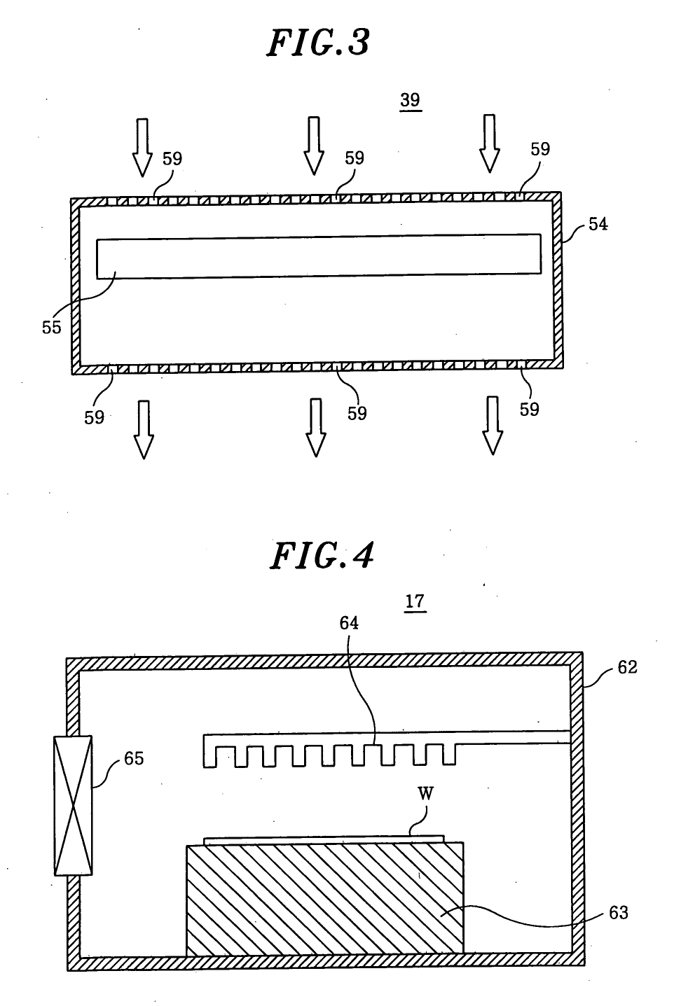

FIG. 3 depicts a vertical sectional view schematically showing a configuration of the dehumidifying unit 39 shown in FIG. 2. Further, upper and lower parts in FIG. 3 are referred to as an “upper side” and a “lower side”, respectively. Furthermore, left and right parts in FIG. 3 are referred to as a “left side” and a “right side”, respectively.

The dehumidifying unit 39 shown in FIG. 3 includes a main body 54 formed of a housing and a rotor-shaped desiccant filter 55 having a honeycomb structure disposed in the main body 54. Further, a number of air holes 59 are arranged on top and bottom surfaces of the main body 54. In the main body 54, the air blown from the upper side by the fan unit 37 passes through the desiccant filter 55 and is blown toward the lower side. The air blown toward the lower side is supplied to the inside of the loader module 13 after passing through the dust removal unit 40 and, then, discharged out of the loader module 13 through the air discharge openings 49 by the duct fan 36.

The desiccant filter 55 is formed of silica gel. When the silica gel having lots of pores gets in contact with the air containing water molecules, the silica gel adsorbs water molecules in the air due to reaction of hydroxyl groups (silanol groups) present on the inner walls of the pores and capillary condensation of the pores. Thus, in the main body 54, the desiccant filter 55 can dehumidify the air blown from the upper side by the fan unit 37.

In FIG. 3, a horizontal length of the desiccant filter 55 is similar to an inner horizontal length of the main body 54. Therefore, the desiccant filter 55 can dehumidify the entire air passing through the inner space of the main body 54.

FIG. 4 represents a vertical sectional view showing the after treatment chamber 17 cut along a line IV-IV shown in FIG. 1. Further, upper and lower parts in FIG. 4 are referred to as an “upper side” and a “lower side”, respectively.

As shown in FIG. 4, the after treatment chamber (reaction product removal chamber) 17 includes a main body 62 formed of a housing; a wafer stage 63, disposed at the lower side in the main body 62, for mounting the wafer W thereon; a high-temperature steam spray nozzle (high-temperature steam supply unit) 64 disposed at the upper side in the main body 62 to face the wafer stage 63; a gate valve 65 that can be freely opened or closed and is disposed on the side surface of the main body 62, particularly, at a position corresponding to the wafer W mounted on the wafer stage 63; and a purge unit (not shown) for purging the air or gas in the main body 62 out of it. Further, the after treatment chamber 17 is connected to the loader module 13 via the gate valve 65 to communicate with the inside of the loader module 13 when the gate valve 65 is opened.

First, the wafer W having the polysilicon layer etched by a plasma of hydrogen bromide gas or chlorine gas in the process module 25 is loaded into the after treatment chamber 17 via the gate valve 65 to be mounted on the wafer stage 63.

Subsequently, the main body 62 starts purging itself after the gate valve 65 is closed. Then, the high-temperature steam spray nozzle 64 sprays high-temperature steam toward the wafer W. At this time, corrosive reaction products, e.g., SiBr₄ or SiCl₄, which are produced on the wafer W in the etching, react with the high-temperature steam. Resultantly, halogen in the corrosive reaction products is reduced to turn out to be a gas such as HBr or HCl, and the corrosive reaction products are resolved. Further, the HBr or HCl is forced to be discharged out of the main body 62 by the purge unit, whereby an inner surface of the main body 62, a surface of the wafer stage 63 and the like are not corroded.

After the high-temperature steam spray nozzle 64 stops spraying the high-temperature steam, the gate valve 65 is opened and the wafer W mounted on the wafer stage 63 is unloaded from the after treatment chamber 17 by the transfer arm unit 19.

As described above, corrosive reaction products formed on the wafer W are removed in the after treatment chamber 17. The after treatment chamber 17 includes the high-temperature steam spray nozzle 64 for spraying high-temperature steam toward the wafer W, thereby definitely bringing the high-temperature steam into contact with the corrosive reaction products. Accordingly, it promotes reduction of halogen in the corrosive reaction products and resolution of the corrosive reaction products.

Further, instead of the high-temperature steam spray nozzle 64, the after treatment chamber 17 may include a high-temperature steam filling unit for supplying high-temperature steam into the main body 62 such that the main body 62 is filled with the high-temperature steam. In this case, the wafer W loaded into the main body 62 is exposed to the high-temperature steam and, thus, the corrosive reaction products formed on the wafer W are removed.

Hereinafter, there will be described a post-etching processing method (processed object transfer method) performed in the substrate processing apparatus 10. After the wafer W is etched by a plasma of hydrogen bromide gas or chlorine gas in the process module 25, the post-etching processing is performed based on a transfer recipe, that is, a transfer program, by the system controller.

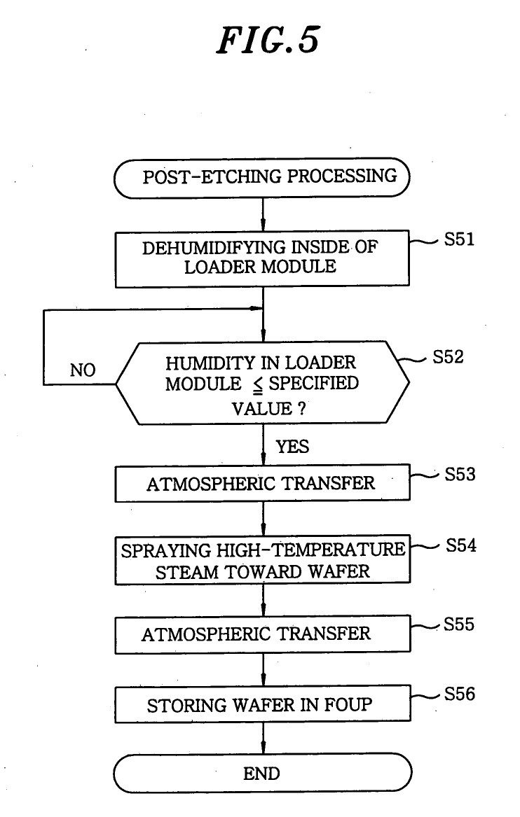

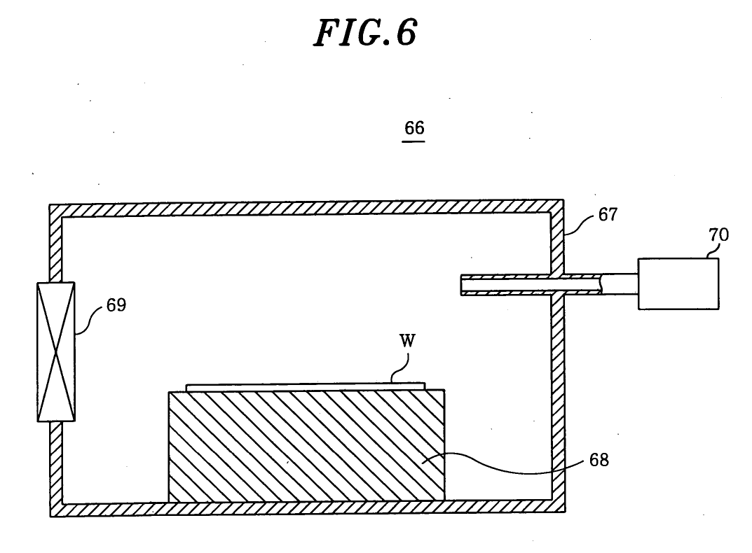

FIG. 5 is a flowchart showing the post-etching processing.

Referring to FIG. 5, first, the inside of the loader module 13 is dehumidified by the FFU 34 (step S51). When a specified time period has elapsed, it is determined whether or not the humidity in the loader module 13 has reached a specified value or becomes smaller than that (step S52).

If the humidity in the loader module 13 is larger than the specified value, processing returns to step S51 to continue dehumidifying the inside of the loader module 13. If the humidity in the loader module 13 becomes equal to or smaller than the specified value, the etched wafer W is loaded into the loader module 13 from the process ship 11 by the transfer arm unit 19, and the wafer W is transferred toward the after treatment chamber 17 in the loader module 13 under an atmospheric pressure (transfer step) (step S53). At this time, since the inside of the loader module 13 has been dehumidified, the wafer W is transferred through the dehumidified air. Thus, the corrosive reaction products formed on the wafer W are prevented from reacting with water in the loader module 13, and neither HBr nor HCl is produced from the wafer W.

Then, the wafer W is loaded into the after treatment chamber 17, wherein the high-temperature steam spray nozzle 64 sprays high-temperature steam toward the loaded wafer W (step S54), whereby the corrosive reaction products formed on the wafer W are removed.

Subsequently, the wafer W having no corrosive reaction products by removing them therefrom is unloaded from the after treatment chamber 17 by the transfer arm unit 19, and the wafer W is transferred toward the FOUP 14 in the loader module 13 under an atmospheric pressure (step S55) to be stored in the FOUP 14 (step S56).

In the processing shown in FIG. 5 carried out by using the loader module 13 in accordance with the first preferred embodiment of the present invention, the wafer W etched by a plasma of hydrogen bromide gas or chlorine gas is transferred through the dehumidified air in the loader module 13. Accordingly, the corrosive reaction products formed on the wafer W are prevented from reacting with water, and neither HBr nor HCl is produced from the wafer W. As a result, the inner wall of the loader module 13 made of stainless steel, aluminum or the like can be prevented from being corroded, thereby preventing its inner wall and surface from being covered with an oxide (e.g., Fe₂O₃ or Al₂O₃) layer. Therefore, it is possible to prevent quality of a semiconductor device fabricated from the wafer W from deteriorating and improve an operation rate of the substrate processing apparatus 10.

Further, in accordance with the processing shown in FIG. 5, whether or not to transfer the wafer W in the loader module 13 is determined depending on the humidity of the loader module 13. Accordingly, corrosive reaction products attached to the wafer W can be further surely prevented from reacting with water in the loader module 13.

Since the FFU 34 of the loader module 13 includes the dehumidifying unit 39 which contains the desiccant filter 55 formed of silica gel, the inside of the loader module 13 can be efficiently dehumidified. Further, since the desiccant filter 55 can be recovered during a dehumidifying process, the desiccant filter 55 can dehumidify the inside of the loader module 13 for a long time period, which, in turn, further improves an operation rate of the substrate processing apparatus 10.

Since the dehumidifying unit 39 is included in the FFU 34 which is embedded in the loader module 13, there is no need to provide additional units outside the loader module 13 and an outward shape of the loader module 13 does not change. Thus, a position of the loader module 13 need not be changed in the factory.

In the after treatment chamber 17 connected to the loader module 13, the high-temperature steam spray nozzle 64 sprays high-temperature steam toward the loaded wafer W, whereby halogen in the corrosive reaction products formed on the wafer W is reduced. Thus, the corrosive reaction products can be resolved to be removed. As a result, it is possible to prevent a semiconductor device fabricated from the wafer W from developing any abnormal defect.

Further, since the after treatment chamber 17 includes the high-temperature steam spray nozzle 64 for supplying high-temperature steam into the chamber, it is possible to definitely bring the high-temperature steam into contact with the corrosive reaction products. Accordingly, it promotes reduction of halogen in the corrosive reaction products and resolution of the corrosive reaction products.

Since the loader module 13 includes the loading port 20 installed on the side surface thereof and the CDA curtain 50, disposed under the FFU 34, for supplying dehumidified air toward the loading port 20, the inside of the FOUP 14 can be maintained in a dry state. Accordingly, it is possible to prevent water from entering into the loader module 13 from the FOUP 14. Thus, corrosive reaction products formed on the wafer W can be surely prevented from reacting with water in the loader module 13.

Further, the loader module 13 includes the ionizer 35 for supplying positive and negative ions into the loader module 13, wherein the supplied ions make the charges to be removed from the wafer W that is likely to be charged in the dehumidified loader module 13. Accordingly, it is possible to prevent the quality of a semiconductor device fabricated from the wafer W from deteriorating.

Since the FOUP mounting table 15 connected to the loader module 13 includes the heat transfer heater 53 for heating the FOUP 14, it is possible to surely remove water from the FOUP 14 and prevent water from entering into the loader module 13 from the FOUP 14.

Further, in the above-mentioned substrate processing apparatus 10, for example, even if the corrosive reaction products are not completely removed from the wafer W in the after treatment chamber 17, the wafer W unloaded from the after treatment chamber 17 is transferred in the dehumidified air in the loader module 13. Thus, neither HBr nor HCl is produced in the loader module 13. Besides, since the FOUP 14 is heated by the heat transfer heater 53 embedded in the FOUP mounting table 15, it can prevent water from being attached to the wafer W in the FOUP 14, so that corrosive reaction products are kept from reacting with water.

Further, the loader module 13 includes the heating unit 38, for heating the air supplied into the loader module 13, which makes HCl and the like produced in the reaction between the corrosive reaction products attached to the wafer W and water be evaporated. Accordingly, it is possible to prevent HCl from being attached to the inner wall of the loader module 13 and the surface of the unit disposed in the loader module 13. Therefore, the inner wall of the loader module 13 made of stainless steel, aluminum or the like can be further surely prevented from being corroded, thereby preventing the inner wall and the surface from being covered with an oxide (e.g., Fe₂O₃ or Al₂O₃) layer.

Furthermore, since the ionizer 35, the CDA curtain 50, the heating unit 38 and the heat transfer heater 53 included in the loader module 13 do not directly dehumidify the inside of the loader module 13, those components may be omitted.

Hereinafter, there will be described an atmospheric transfer chamber in accordance with a second preferred embodiment of the present invention.

The second preferred embodiment has a substantially same configuration and effects as those of the first preferred embodiment except that a supercritical substance is employed instead of the high-temperature steam to remove the corrosive reaction products from the wafer W. Specifically, a loader module 13 is connected to an after treatment chamber 66 to be described later in lieu of the after treatment chamber 17 of the first preferred embodiment. Thus, to avoid redundancy, description of duplicated configuration and effects is omitted and only different configuration and effects will be described later.

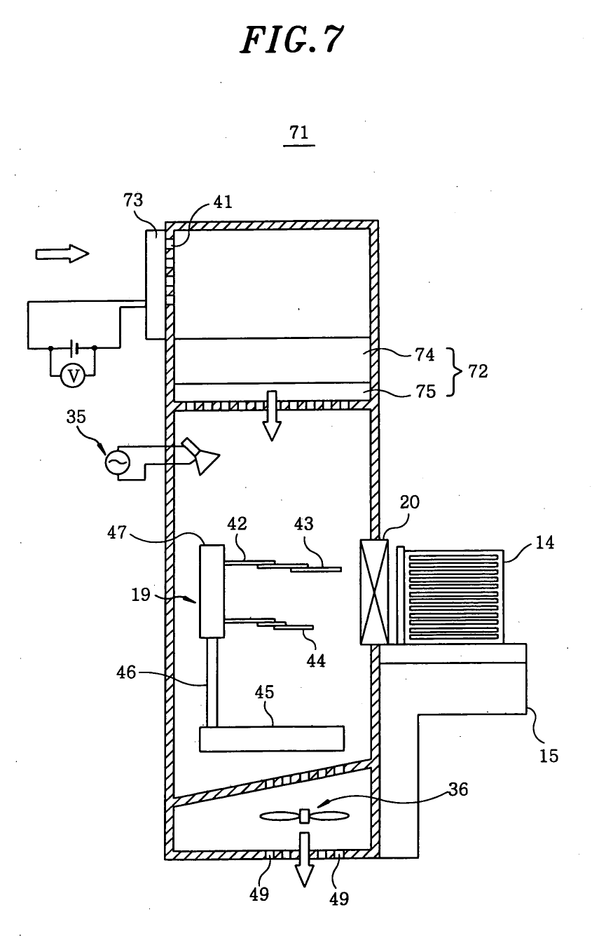

FIG. 6 depicts a cross sectional view showing a schematic configuration of the after treatment chamber connected to the loader module serving as the atmospheric transfer chamber in accordance with the second preferred embodiment.

As shown in FIG. 6, the after treatment chamber (reaction product removal chamber) 66 includes a main body 67 formed of a housing; a wafer stage 68, disposed at a lower side in the main body 67, for mounting a wafer W thereon; a supercritical substance supply nozzle (supercritical substance supply unit) 70, for supplying supercritical substance, to be described later, toward the wafer W mounted on the wafer stage 68; a gate valve 69 that can be freely opened or closed and is disposed on the side surface of the main body 67, particularly, at a position corresponding to the wafer W mounted on the wafer stage 68; a purge unit (not shown) for purging air or gas in the main body 67 out of it; and a heater (not shown) for heating an inside of the main body 67. Further, the after treatment chamber 66 is connected to the loader module 13 via the gate valve 69 to communicate with the inside of the loader module 13 when the gate valve 69 is opened.

The supercritical substance which is supplied from the supercritical substance supply nozzle 70 is a substance having a high temperature and a high pressure beyond its critical temperature and critical pressure (critical point), namely, in a supercritical state. The critical point represents the highest temperature and pressure at which the substance can exist as gas and liquid in equilibrium. In the supercritical state, the densities of gas and liquid phases become identical and the distinction between gas and liquid disappears. Since the supercritical substance has characteristics of the two phases, fluid formed of the supercritical substance (hereinafter, referred to as “supercritical fluid”) enters into a narrow depression, e.g., a trench (groove), in the semiconductor device formed on the wafer W to get in contact with the corrosive reaction products attached to all over the sidewall of the trench.

A supercritical fluid can be formed of H₂O (water), CO₂, rare gas (e.g., Ar, Ne, He), NH₃ (ammonia), CH₄ (methane), C₃H₈ (propane), CH₃OH (methanol), C₂H₅OH (ethanol) or the like. For example, CO₂ becomes supercritical at a temperature of 31.1° C. and a pressure of 7.37 MPa.

In the after treatment chamber 66, in order to maintain a supercritical fluid supplied from the supercritical substance supply nozzle 70 in a supercritical state, an inner pressure of the main body 67 is maintained at a high pressure by the purge unit and an inner temperature of the main body 67 is maintained at a high temperature by the heater. Specifically, when the supercritical fluid is made of CO₂, the inner temperature of the main body 67 is set to range from 31.1° C. to 50° C.; and the inner pressure thereof is maintained at about 7.37 MPa or higher.

Further, the supercritical fluid supplied from the supercritical substance supply nozzle 70 contains a halogen reducing agent such as water or oxygenated water (H₂O₂), used for dissolving the corrosive reaction products. The liquid used for dissolving those is transferred along with the supercritical fluid to reach the trench of the semiconductor device formed on the wafer W.

First, the wafer W having the polysilicon layer that is etched by a plasma of hydrogen bromide gas or chlorine gas in a process module 25 is loaded into the after treatment chamber 66 via the gate valve 69 by a transfer arm unit 19 and, then, mounted on the wafer stage 68.

Subsequently, the main body 67 starts purging itself after the gate valve 69 is closed. Then, the supercritical substance supply nozzle 70 feeds supercritical fluid toward the wafer W, wherein the supercritical fluid enters into the narrow trench together with the halogen reducing agent and the halogen reducing agent gets in contact with the corrosive reaction products attached to the sidewall of the trench. At this time, the aforementioned high-pressure environment formed in the main body 67 accelerates reaction between the halogen reducing agent and the corrosive reaction products. Accordingly, the corrosive reaction products, e.g., SiBr₄ and SiCl₄, in the trench react with the halogen reducing agent. Resultantly, halogen in the corrosive reaction products is reduced to turn out as a gas such as HBr or HCl, and the corrosive reaction products are resolved. Further, the HBr or HCl is attracted to the supercritical fluid due to a liquid characteristic of the supercritical fluid, thereby being removed from the trench.

Further, the HBr or HCl is forced to be discharged out of the main body 67 by the purge unit, whereby an inner surface of the main body 67, a surface of the wafer stage 68 or the like is not corroded.

Subsequently, after the supercritical substance supply nozzle 70 stops feeding the supercritical fluid, the gate valve 69 is opened and the wafer W mounted on the wafer stage 68 is unloaded from the after treatment chamber 66 by the transfer arm unit 19.

In the after treatment chamber 66 connected to the loader module 13 in accordance with the second preferred embodiment of the present invention, the supercritical substance supply nozzle 70 feeds the supercritical fluid, which has liquid and gaseous characteristics and contains a halogen reducing agent, toward the loaded wafer W. Due to its gaseous characteristic, the halogen reducing agent can enter into the trench of the semiconductor device formed on the wafer W. Accordingly, it promotes reduction of halogen in the corrosive reaction products attached to the sidewall of the trench and, thus, the corrosive reaction products can be resolved. Further, due to its liquid characteristic, it attracts the HBr or HCl produced from the resolved corrosive reaction products, whereby the corrosive reaction products can be surely removed from the trench.

Since the supercritical substance supplied from the supercritical substance supply nozzle 70 is formed of CO₂, water, rare gas or the like, the supercritical state can be easily realized, thereby facilitating the removal of the corrosive reaction products. Further, a reducing agent included in the supercritical fluid is formed of water or oxygenated water, it is possible to further promote the reduction of halogen in the corrosive reaction products.

Hereinafter, there will be described an atmospheric transfer chamber in accordance with a third embodiment of the present invention.

The third preferred embodiment has a substantially same configuration and effects as those of the first preferred embodiment except an FFU structure. Specifically, the third embodiment is different from the first embodiment in that FFU does not include a dehumidifying unit and the dehumidifying unit is disposed outside the loader module. Thus, description of repeated configuration and effects is omitted and only different configuration and effects will be described later.

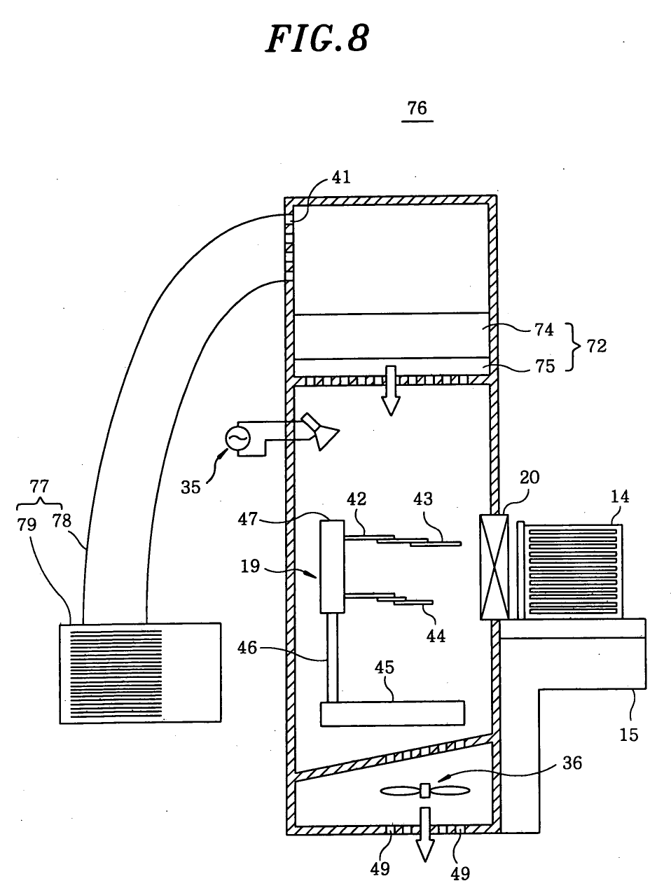

FIG. 7 depicts a cross sectional view showing a schematic configuration of a loader module serving as an atmospheric transfer chamber in accordance with the third preferred embodiment.

As shown in FIG. 7, a loader module 71 includes therein an FFU 72 disposed at an upper side a transfer arm unit 19; an ionizer 35; a duct fan 36 disposed at a lower side; and air inlet openings 41 disposed above the FFU 72 on the sidewall of the loader module 71. Further, the loader module 71 is also provided with a dehumidifying unit (dehumidifier) 73 disposed at an outer sidewall thereof to face the air inlet openings 41.

The FFU 72 includes a fan unit 74 and a dust removal unit 75 installed in the order thus named from the top down. The fan unit 74 has therein a fan (not shown) for blowing air downward, and the dust removal unit 75 has therein a filter (not shown) for collecting dust in the air blown by the fan unit 74.

Further, the dehumidifying unit 73 has a structure capable of passing air therethrough and includes a cooling unit (not shown) which is in contact with the passing air. The cooling unit has a Peltier element which absorbs heat from the air passing by the element. At this time, in the air cooled due to the heat absorption, vapor is condensed into water, which is reserved in the cooling unit, thereby efficiently dehumidifying the air passing through the dehumidifying unit 73. That is, the dehumidifying unit 73 can efficiently dehumidify the air that will be introduced into the loader module 71 by the fan unit 74.

As described above, after the air drawn into the loader module 71 from the outside is dehumidified by the dehumidifying unit 73 and dust in the air is removed by the FFU 72, the air is supplied to a lower side in the loader module 71. In this manner, the air inside the loader module 71 is dehumidified.

Further, the loader module 71 is not provided with configurations corresponding to a CDA curtain 50 and a heat transfer heater 53 included in a loader module 13. Moreover, the loader module 71 includes the aforementioned after treatment chamber 17 or 66 in order to remove corrosive reaction products from the wafer W.

Further, the cooling unit of the dehumidifying unit 73 may have a heat exchanger or a heat pump instead of the Peltier element.

In the loader module serving as an atmospheric transfer chamber in accordance with the third embodiment of the present invention, the dehumidifying unit 73 is disposed at the outside of the loader module 71 and the dehumidifying unit 73 includes the cooling unit for cooling air introduced into the loader module 71, thereby efficiently dehumidifying the air. Thus, the inside of the loader module 71 can be efficiently dehumidified. Further, since the dehumidifying unit 73 is disposed at the outside of the loader module 71, it can be easily arranged to be installed and the configuration of the loader module 71 can be simplified.

Further, since the cooling unit of the dehumidifying unit 73 has the Peltier element, the cooling unit can become compact.

Hereinafter, an atmospheric transfer chamber in accordance with a fourth preferred embodiment of the present invention will be described.

The fourth preferred embodiment has a substantially same configuration and effects as those of the third preferred embodiment except a structure of a dehumidifying unit. Specifically, the fourth embodiment is different from the third embodiment in that the dehumidifying unit includes not a cooling unit but an air conditioner unit. Thus, description of the repeated configuration and effects is omitted and only different configuration and effects will be described hereinafter.

FIG. 8 depicts a cross sectional view showing a schematic configuration of a loader module serving as an atmospheric transfer chamber in accordance with the fourth preferred embodiment.

As shown in FIG. 8, a loader module 76 includes therein an FFU 72 disposed at an upper side; a transfer arm unit 19; an ionizer 35; and a duct fan 36 disposed at a lower side; and an air conditioner module (dehumidifier) 77 disposed at the outside thereof. Further, air inlet openings 41 are disposed above the FFU 72 on the sidewall of the loader module 76.

The air conditioner module 77 includes an air conditioner 79 and a duct 78 for connecting the air conditioner 79 with the air inlet openings 41. The air conditioner 79 having a compressor or a coolant absorbs air around the loader module 76 and efficiently dehumidifies the air. The dehumidified air is blown into the loader module 76 through the duct 78 and the air inlet openings 41. The air blown into the loader module 76 after being dehumidified by the air conditioner 79 is blown downward by the fan unit 74. After dust in the air blown from the fan unit 74 is collected by the dust removal unit 75, the air is supplied to a lower side in the loader module 76. In this manner, the air inside the loader module 76 is dehumidified.

The loader module 76 serving as an atmospheric transfer chamber in accordance with the fourth preferred embodiment of the present invention includes the air conditioner module 77 which has the air conditioner 79 and the duct 78, wherein the air conditioner 79 absorbs air around the loader module 76 and efficiently dehumidifies the air, and the dehumidified air is blown into the loader module 76. Thus, the inside of the loader module 76 can be efficiently dehumidified. Further, since the air conditioner 79 can be easily arranged, it is possible to prevent a configuration of the loader module 76 from being complicated.

Hereinafter, an atmospheric transfer chamber in accordance with a fifth preferred embodiment of the present invention will be described.

The fifth preferred embodiment has a substantially same configuration and effects as those of the third preferred embodiment, but the fifth embodiment is different from the third embodiment in that the transfer chamber includes therein a heating unit instead of the dehumidifying unit. Thus, description of any repeated configuration and effects is omitted and only different configuration and effects will be described later.

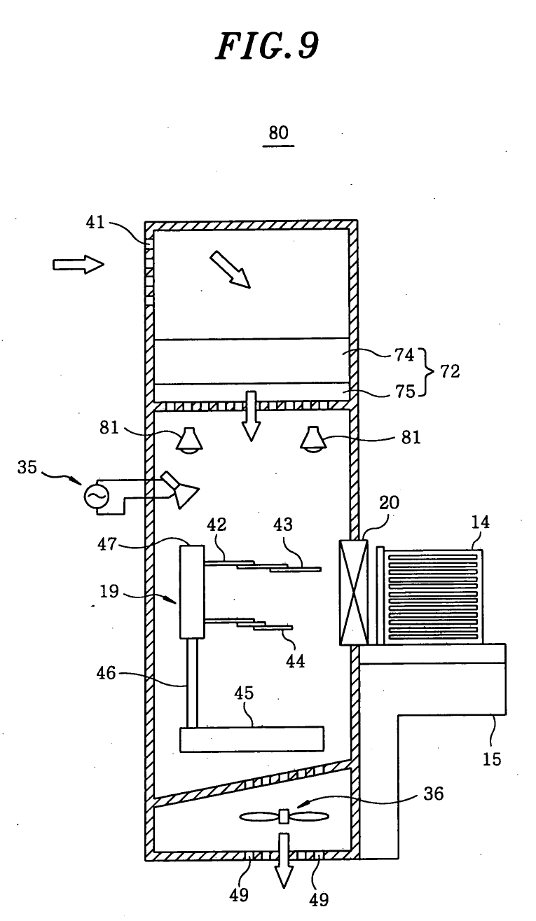

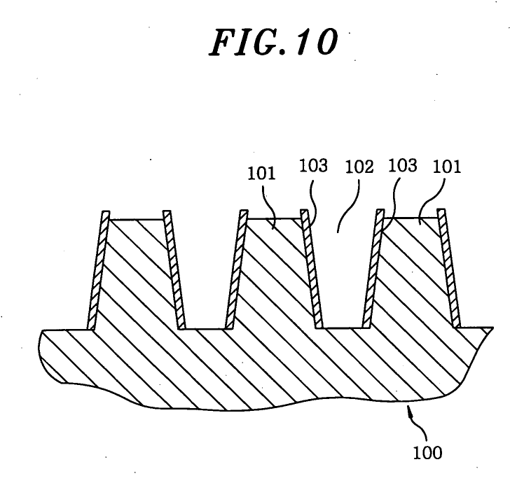

FIG. 9 depicts a cross sectional view showing a schematic configuration of a loader module serving as an atmospheric transfer chamber in accordance with the fifth preferred embodiment.

As shown in FIG. 9, a loader module 80 includes therein an FFU 72 disposed at an upper side; a transfer arm unit 19; an ionizer 35; and a duct fan 36 disposed at a lower side; and a heating unit (interior heating unit) 81 disposed inside the transfer chamber. Further, air inlet openings 41 are disposed above the FFU 72 on the sidewall of the loader module 80.

After dust in the air drawn into the loader module 80 from the outside is removed by the FFU 72, the air is supplied to a lower side in the loader module 80. At this time, the supplied air contains water, and corrosive reaction products on the wafer W transferred in the loader module 80 react with the water, thereby producing HBr or HCl in the loader module 80. The produced acid can be attached to an inner wall of the loader module 80 and the surface of the transfer arm unit 19, whereby the inner wall and the surface may be corroded.

To solve this problem, in the fifth embodiment, the loader module 80 has an in-chamber heating unit 81 therein. The in-chamber heating unit 81 includes a plurality of halogen lamps, and each halogen lamp illuminates the inner wall of the loader module 80 and the surface of the transfer arm unit 19 (hereinafter, simply referred to as “the inner wall and the surface”). At this time, since illuminated inner wall and surface are heated by heat rays emitted from the halogen lamps, the acid generated in the loader module 80 is evaporated as soon as it gets in contact with the inner wall and the surface without being attached thereto. Thus, it is possible to prevent the inner wall and the surface from being corroded in the loader module 80.

Further, the heating unit 81 in the transfer chamber can be anything capable of heating the inner wall and the surface, for example, a ceramic heater or an infrared lamp, without being limited to the plurality of halogen lamps.

In the loader module serving as an atmospheric transfer chamber in accordance with the fifth preferred embodiment of the present invention, since the inside of the loader module 80, specifically, the inner wall of the loader module 80 and the surface of the transfer arm unit 19, are heated, acid produced by reaction of corrosive reaction products formed on the wafer W with water is evaporated all the time, thereby preventing the acid from being attached to the inner wall and the surface. As a result, generation of oxide is suppressed in the loader module 80 and it is possible to prevent the quality of a semiconductor device fabricated from the wafer W from being deteriorated and improve an operation rate of the substrate processing apparatus 10.

In the above-mentioned embodiments, the wafer W that is transferred has the polysilicon layer etched by a plasma of hydrogen bromide gas or chlorine gas, but even when the wafer W which is transferred is etched by a plasma of a halogen-based gas other than the hydrogen bromide gas and chlorine gas, the same effects as in the above-mentioned embodiments can be obtained.

Further, the present invention can be applied to any unit for transferring the wafer W etched by a plasma of a halogen-based gas through the atmosphere without being limited to the loader module.

Further, a storage medium storing therein program codes of software for realizing the functions of the aforementioned preferred embodiments is provided to the system controller. CPU included in the system controller reads the program codes stored in the storage medium and executes them, so that the object of the present invention can be achieved ultimately.

In this case, the program codes themselves read from the storage medium execute the functions of the preferred embodiments described above so that the program codes and the storage medium storing therein the program codes are also part of the present invention.

Further, anything capable of storing the program codes, for example, RAM, NV-RAM, floppy (registered trademark) disk, hard disk, optical disk, magneto-optical disk, CD-ROM, MO, CD-R, CD-RW, DVD (DVD-ROM, DVD-RAM, DVD-RW, DVD+RW), magnetic tape, nonvolatile memory card, and different type of ROM can be employed as the storage medium for providing the program codes. Besides, the program codes may be provided to the system controller by being downloaded from a database, another computer (not shown) connected to the internet, commercial network and local-area network or the like.

Although the functions of the aforementioned preferred embodiments are realized by executing the program codes read by the CPU in the above-described case, based on instructions of the program codes, OS (operating system) and the like installed on the computer may execute the functions partially or entirely, and such an approach is also included in the present invention.

Further, after the program codes read from the storage medium are stored in a memory included in a function extension board inserted in the system controller or a function extension unit connected to the system controller, based on instructions of the program codes, CPU and the like included in the function extension board or the function extension unit may partially or entirely execute the functions of the above-described preferred embodiments. This approach is also part of the present invention.

The program codes may take the form of object codes, program codes executed by an interpreter, script data supplied to OS, or the like.

While the invention has been shown and described with respect to the preferred embodiments, it will be understood by those skilled in the art that various changes and modifications may be without departing from the spirit and scope of the invention as defined in the following claims.

What is claimed is:

1. An atmospheric transfer chamber, connected to an object processing chamber for processing a target object by using a plasma of a halogen-based gas, for transferring the target object therein, the atmospheric transfer chamber comprising:
a dehumidifying unit for dehumidifying air in the atmospheric transfer chamber.

2. The atmospheric transfer chamber of claim 1, wherein the dehumidifying unit includes a desiccant filter.

3. The atmospheric transfer chamber of claim 1, wherein the dehumidifying unit includes a cooling unit for cooling the air introduced into the atmospheric transfer chamber.

4. The atmospheric transfer chamber of claim 3, wherein the cooling unit has a Peltier element.

5. The atmospheric transfer chamber of claim 1, wherein the dehumidifying unit includes an air conditioner.

6. The atmospheric transfer chamber of claim 1, which is connected to a reaction product removal chamber for removing reaction products of a halogen-based gas attached to the target object,
wherein halogen in reaction products attached to the target object is reduced in the reaction product removal chamber.

7. The atmospheric transfer chamber of claim 6, wherein the reaction product removal chamber includes a high-temperature steam supply unit for supplying high-temperature steam into the chamber.

8. The atmospheric transfer chamber of claim 7, wherein the high-temperature steam supply unit sprays the high-temperature steam toward the target object loaded into the reaction product removal chamber, or the target object loaded into the reaction product removal chamber is exposed to the supplied high-temperature steam.

9. The atmospheric transfer chamber of claim 6, wherein the reaction product removal chamber includes a supercritical substance supply unit for supplying a supercritical substance into the chamber, and the supercritical substance contains a halogen reducing agent for reducing halogen in reaction products.

10. The atmospheric transfer chamber of claim 9, wherein the supercritical substance is formed of carbon dioxide, rare gas or water.

11. The atmospheric transfer chamber of claim 10, wherein the reducing agent is formed of water or oxygenated water.

12. The atmospheric transfer chamber of claim 1, comprising:
a container port for connecting the atmospheric transfer chamber with a container storing the target object; and
a dehumidified air supply unit for supplying dehumidified air toward the container port.

13. The atmospheric transfer chamber of claim 1, comprising an ion supply unit for supplying ions into the atmospheric transfer chamber.

14. The atmospheric transfer chamber of claim 1, comprising an air heating unit for heating air supplied into the atmospheric transfer chamber.

15. The atmospheric transfer chamber of claim 1, comprising a container mounting table for mounting thereon a container storing the target object,
wherein the container mounting table includes a container heating unit for heating the container.

16. An atmospheric transfer chamber, connected to an object processing chamber for processing a target object by using a plasma of a halogen-based gas, for transferring the target object therein, the atmospheric transfer chamber comprising:
an interior heating unit for heating an inside of the atmospheric transfer chamber.

17. A transfer method of a target object which is processed by using a plasma of a halogen-based gas, the method comprising the step of:
transferring the target object inside a dehumidified atmospheric transfer chamber.

18. A program executable on a computer for performing a transfer method of a target object which is processed by using a plasma of a halogen-based gas, comprising:
a transfer module for transferring the target object inside a dehumidified atmospheric transfer chamber.

19. A computer readable storage medium for storing therein a program executable on a computer for performing a transfer method of a target object which is processed by using a plasma of a halogen-based gas,
wherein the program includes a transfer module for transferring the target object inside a dehumidified atmospheric transfer chamber.

20. The storage medium of claim 19, wherein the program includes a load module for loading the target object into a reaction product removal chamber for removing reaction products of a halogen-based gas attached to the target object; and a reduction module for reducing halogen in reaction products attached to the loaded target object.

21. The storage medium of claim 20, wherein the program includes a high-temperature steam supply module for supplying high-temperature steam into a reaction product removal chamber.

22. The storage medium of claim 20, wherein the program includes a supercritical substance supply module for supplying a supercritical substance into the reaction product removal chamber, and the supercritical substance contains a halogen reducing agent for reducing halogen in reaction products.

23. The storage medium of claim 19, wherein the program includes a determination module for determining whether the target object is to be transferred inside the atmospheric transfer chamber or not depending on a humidity of the atmospheric transfer chamber.
